(19) United States
(12) Patent Application Publication
(10) Pub. No.: US 2005/0062131 A1
(43) Pub. Date: Mar. 24, 2005

(54) A1/A1Ox/A1 resistor process for integrated circuits

(76) Inventors: James Matthew Murduck, Ellicott, MD (US); Arnold Herbert Silver, Rancho Palos Verdes, CA (US)

Correspondence Address: KATTEN MUCHIN ZAVIS ROSENMAN, 525 WEST MONROE STREET, CHICAGO, IL, 60661-3693, US

(21) Appl. No.: 10/670,101

(22) Filed: Sep. 24, 2003

(51) Int. Cl. H01L 29/00

(52) U.S. Cl. 257/536; 257/537

(57) ABSTRACT

A structure and a method for forming a vertical resistor on a superconducting integrated circuit. The resistance structure is formed from a Al/AlOₓ/Al material system. In particular, the resistance structure includes a layer of aluminum, in-situ oxidation of the aluminum surface and further deposition of aluminum. The resistance of the Al/AlOₓ/Al structure primarily comes from the aluminum oxide layer rather than the aluminum. As such, any aluminum removed during the interconnect pre-cleaning process will have a negligible impact on the overall resistance of the structure.

### BACKGROUND OF THE INVENTION

1. Field of the Invention

The present invention relates to superconducting devices and more particularly to a method for forming a vertical resistor on an integrated circuit, for example, a superconducting integrated circuit, using Al/AlOₓ/Al, which not only reduces the chip area of the resistor but provides across wafer uniformity as a function of the self-limiting oxidation of the aluminum and is not a strong function of the deposition uniformity since the spreading resistance effects occur in a relatively low resistance portion of the resistor structure and thus has a negligible effect on the overall resistance.

2. Description of the Prior Art

Integrated circuits formed with superconducting junctions are generally known in the art. An example of such an integrated circuit is disclosed in commonly owned U.S. Pat. No. 5,892,243, hereby incorporated by reference. Such superconducting junctions are known as Josephson junctions. Various types of Josephson junctions are known, such as disclosed in U.S. Pat. Nos. 4,785,426; 4,985,117; 5,278,140; 5,411,937 and 5,560,936.

In general, Josephson junctions are formed on a substrate, such as Si or thermally oxidized Si. A superconducting material is deposited on a substrate forming two contiguous superconducting regions. Such superconducting materials are known to be selected from materials, such as, Nb, NbN, NbCN, NbTiN, Pb. Nb and NbN are known to be preferred superconducting materials.

Such superconducting integrated circuits are known to be used to form logic circuits. Examples of such logic circuits are disclosed in U.S. Pat. Nos. 4,092,553; 4,371,796; 4,501,975; 4,785,426 and 5,051,627 all hereby incorporated by reference. Such superconducting logic circuits are adapted to be used in a relatively wide range of applications, such as digital signal processing systems and high-performance network switching. Such applications utilize Josephson junctions as well as superconductive quantum interference devices (SQUID) in which two or more Josephson junctions are connected together in a superconducting loop. Examples of such SQUID devices are disclosed in U.S. Pat. Nos. 4,785,426; 5,135,908 and 5,278,140, hereby incorporated by reference.

One type of logic circuits is known as a single flux quantum (SFQ) type circuit. Examples of such SFQ circuits are disclosed in U.S. Pat. Nos. 5,942,997 and 5,552,735. In such SFQ circuits, each logic operation corresponds to a single flux quantum transition of a Josephson junction or SQUID. Essentially data is stored as a magnetic flux quanta in the conductor of the SQUID. Data is transmitted between gates by a current pulse resulting from SFQ transitions of logic operations.

New applications have been developed, for example, satellite applications, in which the integrated circuit dimensions need to be reduced. For example, high speed SFQ circuitry requires relatively high circuit density to allow increased functions per chip and increased speed of operation. Such circuitry requires shunting resistors, known to be laid out such that the current flows parallel to the substrate. In such a configuration, the shunting resistor consumes much of the chip area and adds to the parasitic inductance of the circuit. In order to solve this problem, attempts have been made to form vertical resistors. With such vertical resistors, the current flows normal to the substrate and takes up relatively less chip area than known resistors and have relatively less parasitic inductance. However, there are problems associated with such vertical resistors in these applications. In particular, such shunt resistors are normally in contact with a superconducting film which forms a superconducting interconnect material, such a niobium (Nb) or nitrogen doped niobium (NbN). As such, the resistor material needs to be cleaned prior to deposition of the Nb or NbN. As is known in the art, the cleaning process significantly reduces the quantity and value of the resistor. As such, the uniformity of the resistance across the chip and wafer becomes dependent upon the cross wafer uniformity of the thickness of the resistor material. Thus, there is a need for a method for forming vertical resistors on an integrated circuits that is less affected by processes, such as cleaning, prior to the deposition of the superconducting interconnect material.

### SUMMARY OF THE INVENTION

The present invention relates to a structure and a method for forming a vertical resistor on a superconducting integrated circuit. The resistance structure is formed from a Al/AlOₓ/Al material system. In particular, the resistance structure includes a layer of aluminum, in-situ oxidation of the aluminum surface and further deposition of aluminum. The resistance of the Al/AlOₓ/Al structure primarily comes from the aluminum oxide layer rather than the aluminum. As such, any aluminum removed during the interconnect pre-cleaning process will have a negligible impact on the overall resistance of the structure. The value of resistance of the vertical resistors fabricated in this fashion can be varied by varying the oxygen pressure during oxidation. Varying the oxidation pressure from 1 to 80 mT oxygen can create resistors with resistances from 3 to 0.03 ohms for a given junction size.

### DESCRIPTION OF THE DRAWINGS

These and other advantages of the present invention can be readily understood with reference to the following specification and attached drawings wherein:

FIG. 1 is an exemplary embodiment of the invention in which the resistance structure in accordance with the present invention is formed as a planar structure.

FIG. 2 is an alternative embodiment of the invention in which the resistance structure is formed as an edge resistor.

FIGS. 3a-3e illustrate exemplary step-by-step process diagrams illustrating the various process steps involved in forming a resistance structure in accordance with the present invention.

### DETAILED DESCRIPTION

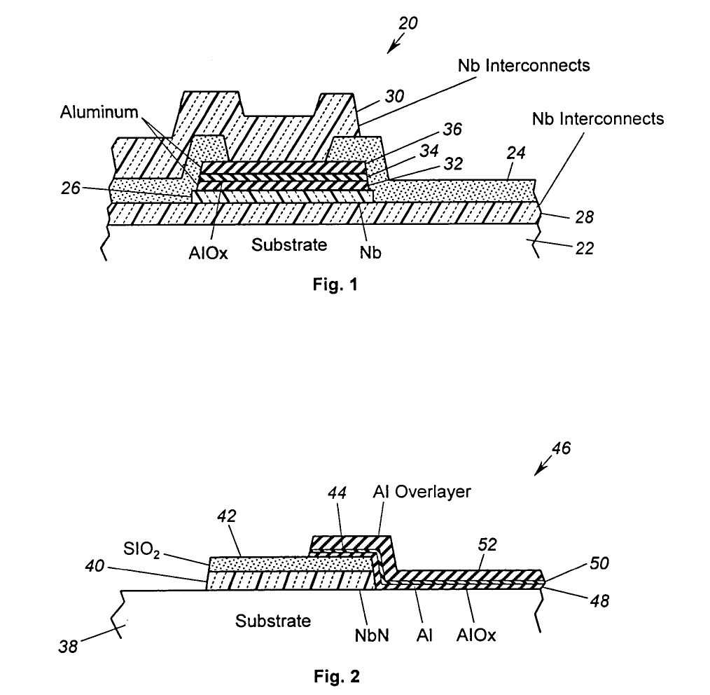

The present invention relates to a vertical resistance structure for use with integrated circuits which include superconducting junctions or films. An example of such an integrated circuit structure is disclosed in commonly owned U.S. Pat. No. 5,892,243, hereby incorporated by reference. Such circuits have been known to employ shunting resistors formed as vertical resistance structures. An example of a known superconducting circuit utilizing vertical shunting resistors is disclosed in: P. Wolf, “Use of Paramagnetic or Other Impurities in Josephson Technology”, IBM Technical Disclosure Bulletin, Vol. 18, No. 8, January 1976, page 2645. As discussed above, the resistance structure is normally cleaned prior to the deposition of the interconnect material which results in a resistance that is a function of the uniformity of the thickness of the material across the wafer. The present invention solves this problem by utilizing a material system in which the cleaning process has a negligible effect on the resistance. In particular, as will be illustrated in three exemplary configurations, illustrated in FIGS. 1-3, the process and structure in accordance with the present invention essentially consists of depositing a layer of aluminum. After the aluminum layer is deposited, the surface of the aluminum layer is allowed to oxidize in-situ. After the oxidation, an additional layer of aluminum is deposited. In such a configuration, the resistance of the structure is primarily related to the aluminum oxide. The aluminum layers which sandwich the aluminum oxide form only a low resistance portion of the resistance structure. As such, any aluminum removed during the cleaning process only has a negligible effect on the overall resistance of the device. The process thus provides cross wafer uniformity as a function of the aluminum self-limiting oxidation thus making the process suitable for large wafer processing.

The value of resistance of the vertical resistors fabricated in this fashion can be varied by varying the oxygen pressure during oxidation. Varying the oxidation pressure from 1 to 80 mT can create resistors with resistances from 3 to 0.03 ohms for a given junction size.

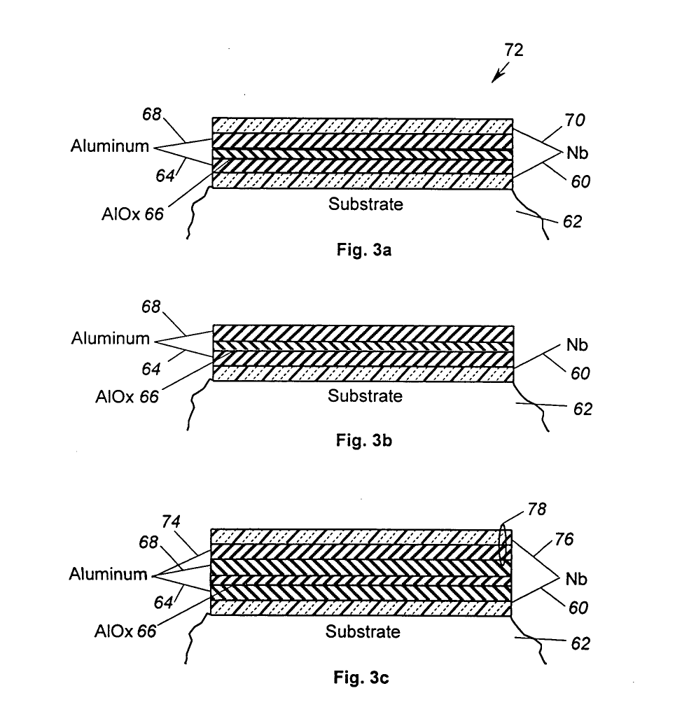

The process is amenable to be formed with a planar configuration as illustrated in FIG. 1 or as edge device as illustrated in FIG. 2. The process of forming the resistance structure in accordance with the present invention is suitable for use in various types of superconducting integrated circuits. An exemplary superconductor integrated circuit is disclosed in commonly-owned U.S. Pat. No. 5,892,243 as well as in U.S. Pat. No. 5,135,908. The superconductor integrated circuits do not form part of the present invention and thus only a sufficient portion of the integrated circuit structure is described and illustrated to provide an understanding of the invention.

Referring to FIG. 1, a planar vertical resistance structure is illustrated and generally identified with the reference numeral 20. As shown, the resistance structure 20 is formed as part of a superconducting integrated circuit which includes a substrate 22 and dielectric 24, for example, as disclosed in commonly-owned U.S. Pat. No. 5,892,243. The planar resistance structure 20, consisting of an Al/AlOₓ/Al layer may be formed on top of a niobium Nb layer 26, which, in turn, is formed on a niobium interconnect layer 28. A niobium interconnect layer 30 maybe deposited by conventional techniques on top of the Al/AlOₓ/Al structure.

As shown in FIG. 1, the planar resistance structure includes an aluminum layer 32 formed on top of the niobium layer 26. As discussed above, the surface of the aluminum layer Al is allowed to oxidize to form an AlOₓ layer 34. Another layer of aluminum 36 is deposited on the AlOₓ layer in order to form the planar resistance structure 20.

As mentioned above, the aluminum layer 36 is normally cleaned by conventional techniques, such as, ion-beam etching or RF plasma etching, prior to deposition of the Nb interconnect material. Such cleaning processes are known to remove a portion of the resistance material systems. As such, a portion of the aluminum layer 36 is removed by the cleaning process prior to deposition of Nb interconnect layer 30. Since the resistance of a material is known to be proportional to the quantity or volume of the material, such removal of a portion of the aluminum layer 36 normally results in lowering of the overall resistance. However, by choosing a Al/AlOₓ/Al material system for the resistance structure, such removal will have a negligible effect on the overall resistance since the major or dominant portion of the resistance is from the AlOₓ layer 34. As such, the process lends itself to a cross wafer uniformity as a function of the aluminum self-limiting oxidation and is not a strong function of the deposition uniformity or the amount removed during the cleaning process.

Another exemplary embodiment of the invention is illustrated in FIG. 2. In this embodiment, the resistance structure is configured in a step configuration. In particular, the resistance structure is formed on a superconductor integrated circuit which includes a substrate 38, nitrogen-doped niobium NbN layer 40 and a dielectric layer 42, formed from, for example, silicon dioxide SiO₂. In this configuration, the NbN layer 40 and the dielectric layer 42 are configured to form a step 44. The Al/AlOₓ/Al structure, generally identified with the reference numeral 46, is formed in a step configuration to be in contact with the substrate layer 38, the edge 44 and the dielectric layer 42 forming a step structure as generally shown in FIG. 2.

In this embodiment, an aluminum layer 48 is deposited on the surface of the substrate 38, the step 44 and a portion of the dielectric layer 42 are defined by lithograpic techniques. The surface of the aluminum layer 48 is allowed to oxidize forming an aluminum AlOₓ layer 50. Another aluminum layer 52 is then deposited on top of the AlOₓ layer 50. As shown in this embodiment, the aluminum layer 52 may have a relatively greater thickness than the aluminum layer 48 to account for the material lost during the cleaning process.

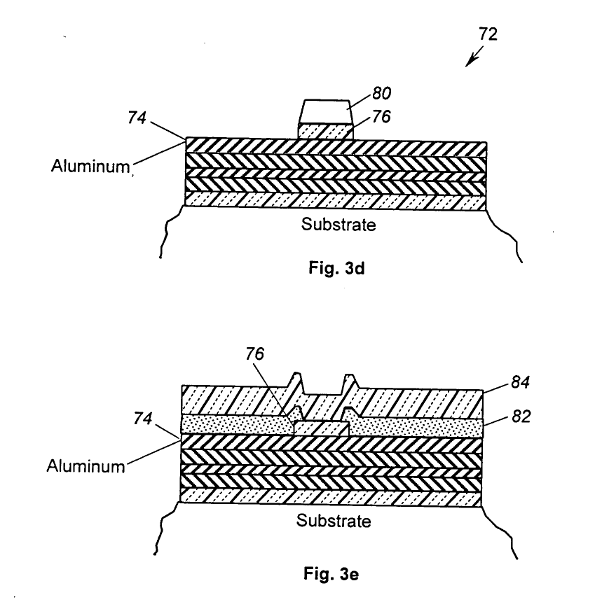

FIGS. 3a-3e illustrate exemplary step-by-step process diagrams for forming a resistance structure in accordance with the present invention. Initially, a niobium layer 60 may be deposited on a substrate 62, for example, 200 nm (nanometers) thick. An aluminum layer 64, is then deposited on top of the niobium layer 60 by conventional techniques. In-situ oxidation of the surface of the aluminum layer 64 is allowed until approximately 1 nm layer AlOₓ is formed, forming a AlOₓ layer 66. Another aluminum layer 68, for example, 8 nm, is formed on top of the AlOₓ layer 66. Another niobium Nb layer 70 may be deposited on top of the aluminum layer 68 to form a pentalayer structure 72 illustrated in FIG. 3a.

Referring to FIG. 3b, the pentalayer structure 72 is etched to form a junction counterelectrode, for example, as disclosed in commonly-owned U.S. Pat. No. 5,892,243. The etching is controlled so as only to remove the top niobium layer 70 (FIG. 3a). Subsequently, as shown in FIG. 3c, an additional niobium Nb layer 76, for example 50 nm, is deposited upon the aluminum layer 74, forming an aluminum/niobium bilayer, generally identified with the reference numeral 78, formed on top of the structure illustrated in FIG. 3b. As shown in 3d, a photoresist 80 is spun onto the structure and developed by lithographic techniques in order to define the top portion of the vertical resistor. In addition, the top layer of 76 of niobium is etched to expose the top most layer of aluminum layer 74.

A dielectric, such as SiO₂, 150 nm, is deposited by sputter deposition on top of the structure illustrated in FIG. 3d. The structure is then masked and etched to form a via through the dielectric layer 82 to the vertical resistor. Subsequently, a niobium interconnect layer 84 may be deposited on top of the structure illustrated in FIG. 3e, for example, 500 nm to form the vertical resistor in accordance with the present invention.

In all of the embodiments, the aluminum is fabricated in such fashion so as not to allow the proximity effect to extend to the aluminum oxide layer. This can be accomplished by 1) sufficiently thickening the layers of aluminum; 2) decreasing the mean free path within the aluminum by a lattice disorder; 3) or intentionally depositing a low mean free path material to reduce the coherence length within the resistor. Titanium layers may be used to reduce the proximity effect within the resistor without adding significantly to the overall resistance.

In order to prevent the proximity effect from extending into the aluminum oxide layer, it is important that the layer overlying the AlOₓ barrier be thick enough or “dirty” enough to prevent superconducting tunneling through the barrier. As such, the layer of aluminum overlying the AlOₓ barrier must be greater than 30 nm. In accordance with the second approach discussed above, this thickness can be reduced by making “dirty” aluminum. As is known in the art, “dirtying” can be accomplished by doping the aluminum with paramagnetic impurities or with small amounts of oxygen O or nitrogen N, for example, as generally discussed in “Use of Paramagnetic or Other Impurities in Josephson Technology”, by P. Wolf, IBM Technical Disclosure Bulletin, Vol. 18, No. 8, January 1978, pgs. 26-45, hereby incorporated by reference. For example, the aluminum can be deposited relatively slowly in the presence of the partial pressure of oxygen or nitrogen. The aluminum should be at least greater than 10 nm thick. The third approach, discussed above, consists of depositing greater than 10 nm of any number of materials with intrinsically lower coherence length, such as, titanium, molybdenum or nitrogen poor niobium nitride on the AlOₓ.

Obviously, many modifications and variations of the present invention are possible in light of the above teachings. Thus, it is to be understood that, within the scope of the appended claims, the invention may be practiced otherwise than as specifically described above.

1. A process for forming a resistance structure comprising the steps of:
a) depositing a first layer of aluminum;
b) oxodizing the surface of said first layer of aluminum defining an oxidized layer; and
c) depositing a second layer of aluminum on said oxidized layer forming a resistance structure.

2. The process as recited in claim 1, wherein said resistance structure is formed as a vertical resistance structure.

3. The process as recited in claim 1, wherein said resistance structure is formed as a planar structure.

4. The process as recited in claim 1, wherein said resistance structure is formed in a step configuration.

5. The process as recited in claim 1, wherein said oxidizing step includes controlling the oxygen pressure during oxidation.

6. The process as recited in claim 5, wherein said oxidization pressure is controlled in order to control the resistance of said resistance structure.

7. The process as recited in claim 1, further including the step of cleaning said second layer of aluminum.

8. The process as recited in claim 7, wherein said cleaning step includes ion beam etching.

9. The process as recited in claim 7, wherein said cleaning step includes RF plasma beam etching.

10. The process as recited in claim 1, further including the step of doping said second layer of aluminum.

11. The process as recited in claim 10, wherein said doping step includes doping said second layer of aluminum with paramagnetic impurities.

12. The process as recited in claim 10, wherein said doping step includes doping said second layer of aluminum with oxygen.

13. The process as recited in claim 10, wherein said doping step includes doping said second layer of aluminum with nitrogen.

14. A process for forming a resistance structure comprising the steps of:
a) depositing a first layer of aluminum;
b) oxodizing the surface of said first layer of aluminum defining an oxidized layer; and
c) depositing a material on said oxidized layer to prevent superconducting tunneling.

15. The process as recited in claim 14, wherein step c includes depositing titanium on said oxidized layer.

16. The process as recited in claim 14, wherein step c includes depositing molybdenum on said oxidized layer.

17. The process as recited in claim 14, wherein step c includes depositing nitrogen on said oxidized layer.

18. The process as recited in claim 14, wherein step c includes depositing niobium nitride on said oxidized layer.

19. A resistance structure adapted to be formed on an integrated circuit, the resistance structure comprising:
a first layer of aluminum;
a layer of aluminum oxide;
a second layer of aluminum, configured such that said layer of aluminum oxide is sandwiched between said first and second layers of aluminum.

20. The structure as recited in claim 19, wherein said second layer of aluminum is doped.

21. The structure as recited in claim 20, wherein said second layer of aluminum is doped with oxygen.

22. The structure as recited in claim 20, wherein said second aluminum layer is doped with nitrogen.

23. A resistance structure adapted to be formed on an integrated circuit, the resistance structure comprising:
a first layer of aluminum;
a layer of aluminum oxide defining an oxide layer; and
a layer formed on top of said oxidized layer, formed from a material selected to prevent superconducting tunneling.

24. The resistance structure as recited in claim 23, wherein said material is at least 30 nm of aluminum.

25. The resistance structure as recited in claim 23, wherein said material is aluminum doped with paramagnetic impurities.

26. The resistance structure as recited in claim 23, wherein said material is aluminum doped with oxygen.

27. The resistance structure as recited in claim 23, wherein said material is aluminum doped with nitrogen.

28. The resistance structure as recited in claim 23, wherein said material is titanium.

29. The resistance structure as recited in claim 23, wherein said material is molybdenum.

30. The resistance structure as recited in claim 23, wherein said material is niobium nitride.

31. A process for forming a resistance structure, the process comprising the steps of:
(a) providing a substrate;
(b) depositing a first niobium layer on said substrate;
(c) depositing a first aluminum layer on said niobium layer;
(d) allowing a portion of said aluminum layer to oxidize forming an oxidized layer;
(e) depositing a second aluminum layer on said oxidized layer;
(f) depositing a second niobium layer on said second aluminum layer forming a pentalayer structure;
(g) etching said pentalayer structure to remove said second niobium layer;
(h) depositing said a third niobium layer on said second aluminum layer forming an aluminum/niobium bilayer;
(i) depositing and developing a photoresist on said bilayer to define a top portion of a vertical resistor;
(j) etching said third layer of niobium to expose said second aluminum layer defining an exposed aluminum layer;
(k) applying a dielectric on top of said second niobium layer and said exposed aluminum layer
(l) etching said dielectric to form a via to said second aluminum layer; and
(m) depositing a niobium interconnect layer.

32. A process for forming a resistance structure, the process comprising the steps of:
(a) providing a substrate;
(b) depositing a first niobium layer on said substrate;
(c) depositing a first aluminum layer on said first niobium layer;
(d) allowing a portion of said first aluminum layer to oxidize forming an oxidized layer;
(e) depositing a second aluminum layer on said oxidized layer;
(f) depositing a dielectric on a portion of said second aluminum layer and said substrate defining an exposed portion of said second aluminum layer; and
(g) depositing said a second niobium layer on top of said exposed portion of said second aluminum layer and said dielectric.

33. A process for forming a resistance structure comprising the steps of:
(a) providing a substrate;
(b) depositing a layer of NbN on a portion of said substrate;
(c) depositing a dielectric on said NbN layer;
(d) depositing a first layer of aluminum on said dielectric layer and on said substrate adjacent said NbN layer forming a step;
(e) allowing a portion of said first aluminum layer to oxidize defining an oxidized layer; and
(f) depositing a second layer of aluminum on said oxidized layer.
